(19) United States
(12) Patent Application Publication
(10) Pub. No.: US 2024/0276837 A1
(43) Pub. Date: Aug. 15, 2024

(54) DISPLAY PANEL AND DISPLAY TERMINAL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Lei Hu, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/617,302

(22) PCT Filed: Nov. 29, 2021
(86) PCT No.: PCT/CN2021/134171

§ 371 Date: Mar. 15, 2024

(30) Foreign Application Priority Data
Oct. 20, 2021 (CN) 202111219998.0

(51) Int. Cl. H10K 59/80; H10K 102/00

(52) U.S. Cl. CPC H10K 59/871; H10K 2102/311

(57) ABSTRACT

The present application discloses a display panel and a display terminal. The display panel includes a display panel body, and a support layer including a pattern portion corresponding to the bending portion, and a flat portion corresponding to the non-bending portion; wherein the pattern portion includes at least one groove, and a transition portion where the groove is connected to the flat portion is disposed with a chamfer. The present application can avoid a stress concentration of the pattern portion of the support layer, and prevent an occurrence of cracks, thereby improving bending performance.

### TECHNICAL FIELD

The present application relates to a display field, in particular to a display panel and a display terminal.

### BACKGROUND

A flexible display device such as a flexible organic light-emitting display device (OLED) has been widely used in daily life. Generally, a support layer is provided on a back side of the organic light-emitting display device. A material of the support layer may be stainless steel (SUS) or the like. The support layer not only can support the flexible display device, but also improve a bending recovery of the flexible display device, thereby avoiding creases caused by bending a flexible material repeatedly, and improving consumer experience. However, a support layer that is too thin often has poor experience, and a support layer that is too thick cannot be repeatedly bent. Therefore, how to make a metal layer resistant to bending and provide a good support is an urgent problem for major manufacturers to solve. At present, a usual practice is to carry out a patterning design in a bending area of the support layer, and to hollow out or to thin the bending area of the support layer, but a pattern is prone to a stress concentration, which leads to cracks occurring and reduces a reliability of the support layer.

### SUMMARY OF INVENTION

### Technical Problem

An embodiment of the present application provides a display panel and a display terminal, which can solve a problem that a pattern is prone to a stress concentration, which leads to cracks and reduces a reliability of a support layer.

### Solution to Technical Problem

### Technical Solution

An embodiment of the present application provides a display panel comprising:

A display panel body including at least one bending portion and a non-bending portion;

A support layer provided on a back side of the display panel body, the support layer including a pattern portion corresponding to the bending portion and a flat portion corresponding to the non-bending portion;

Wherein the pattern portion includes at least one groove, and a transition portion where the groove is connected to the flat portion is chamfered.

Optionally, in some embodiments of the present application, the transition portion where the groove is connected to the flat portion is disposed with a first chamfer, and a shape of the first chamfer is a chamfer with a circular arc shape or a chamfer having a plurality of line segments.

Optionally, in some embodiments of the present application, the first chamfer has the shape of the chamfer having the plurality of the line segments, and two line segments adjacent to each other are connected in smooth transition.

Optionally, in some embodiments of the present application, a bottom of the groove is arc-shaped.

Optionally, in some embodiments of the present application, the groove comprises a bottom, and a side wall connected between the bottom and the flat portion, a transition portion where the side wall is connected to the bottom of the groove is disposed with a second chamfer.

Optionally, in some embodiments of the present application, the groove comprises a plurality of side walls, and a transition portion where the side walls adjacent to each other are connected is disposed with a third chamfer.

Optionally, in some embodiments of the present application, the bending portion comprises a bending shaft, the first chamfer comprises a first sub-chamfer and a second sub-chamfer, the second sub-chamfer is located on the bending shaft, and a radius of the second sub-chamfer is different from a radius of the first sub-chamfer.

Optionally, in some embodiments of the present application, the radius of the second sub-chamfer is greater than the radius of the first sub-chamfer.

Optionally, in some embodiments of the present application, the support layer comprises two grooves intersected with each other, and an edge of a transition portion where the two grooves intersect is arc-shaped or a shape of a plurality of line segments connected in smooth transition.

Optionally, in some embodiments of the present application, the pattern portion is located on a surface of the support layer away from the display panel body.

Accordingly, an embodiment of the present application further provides a display terminal including a terminal and a display panel, the terminal is integrated with the display panel, and the display panel comprises:
A display panel body including at least one bending portion and a non-bending portion;
A support layer provided on a back side of the display panel body, the support layer including a pattern portion corresponding to the bending portion and a flat portion corresponding to the non-bending portion;
Wherein the pattern portion includes at least one groove, and a transition portion where the groove is connected to the flat portion is chamfered.

Optionally, in some embodiments of the present application, the transition portion where the groove is connected to the flat portion is disposed with a first chamfer, and a shape of the first chamfer is a chamfer with a circular arc shape or a chamfer having a plurality of line segments.

Optionally, in some embodiments of the present application, the first chamfer has the shape of the chamfer having the plurality of the line segments, and two line segments adjacent to each other are connected in smooth transition.

Optionally, in some embodiments of the present application, a bottom of the groove is arc-shaped.

Optionally, in some embodiments of the present application, the groove comprises a bottom, and a side wall connected between the bottom and the flat portion, a transition portion where the side wall is connected to the bottom of the groove is disposed with a second chamfer.

Optionally, in some embodiments of the present application, the groove comprises a plurality of side walls, and a transition portion where the side walls adjacent to each other are connected is disposed with a third chamfer.

Optionally, in some embodiments of the present application, the bending portion comprises a bending shaft, the first chamfer comprises a first sub-chamfer and a second sub-chamfer, the second sub-chamfer is located on the bending shaft, and a radius of the second sub-chamfer is different from a radius of the first sub-chamfer.

Optionally, in some embodiments of the present application, the radius of the second sub-chamfer is greater than the radius of the first sub-chamfer.

Optionally, in some embodiments of the present application, the support layer comprises two grooves intersected with each other, and an edge of a transition portion where the two grooves intersect is arc-shaped or a shape of a plurality of line segments connected in smooth transition.

Optionally, in some embodiments of the present application, the pattern portion is located on a surface of the support layer away from the display panel body.

### Beneficial Effects of Invention

### Beneficial Effects

In the embodiment of the present application, a display panel and a display terminal are provided. By providing a first chamfer at a transition portion where a groove and a flat portion are connected, or/and a second chamfer at a transition portion where a side wall of the groove and a bottom of the groove are connected, sharp corners or edges caused by the groove can be completely eliminated, so that each portion smoothly transitions, thereby relieving a stress concentration. The present application is particularly suitable for a display panel having two bending portions in an intersected bending direction, to avoid a stress concentration of a pattern portion of a support layer, and prevent an occurrence of cracks, thereby improving a bending performance and a reliability of the display panel.

### BRIEF DESCRIPTION OF THE DRAWINGS

### Description of the Drawings

In order to more clearly illustrate the technical solutions in the embodiments of the present application, the accompanying drawings required for use in the description of the embodiments will be briefly described below. It will be apparent that the accompanying drawings in the following description are merely some embodiments of the present application, and other drawings may be obtained from these drawings without creative effort by those skilled in the art.

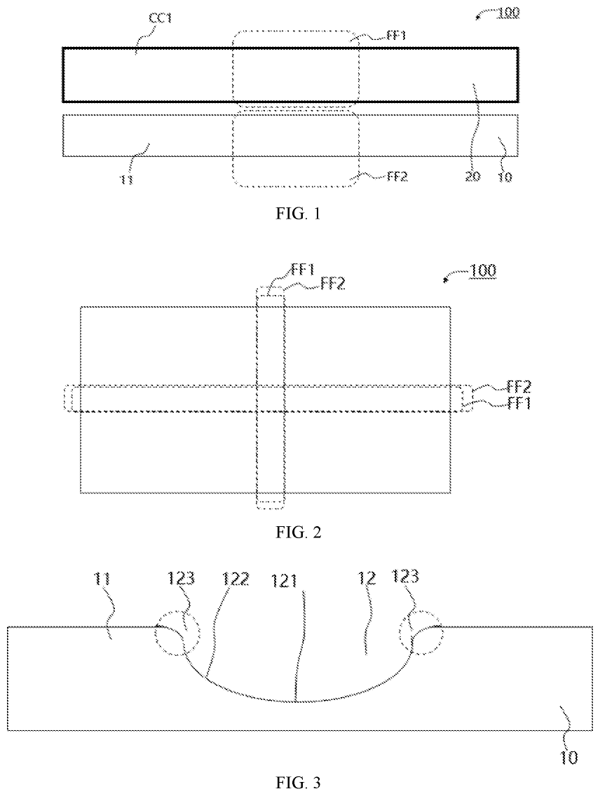

FIG. 1 is a cross-sectional schematic diagram of a display panel according to an embodiment of the present application.

FIG. 2 is a top schematic diagram of the display panel according to an embodiment of the present application.

FIG. 3 is a first cross-sectional schematic diagram of a support layer according to an embodiment of the present application.

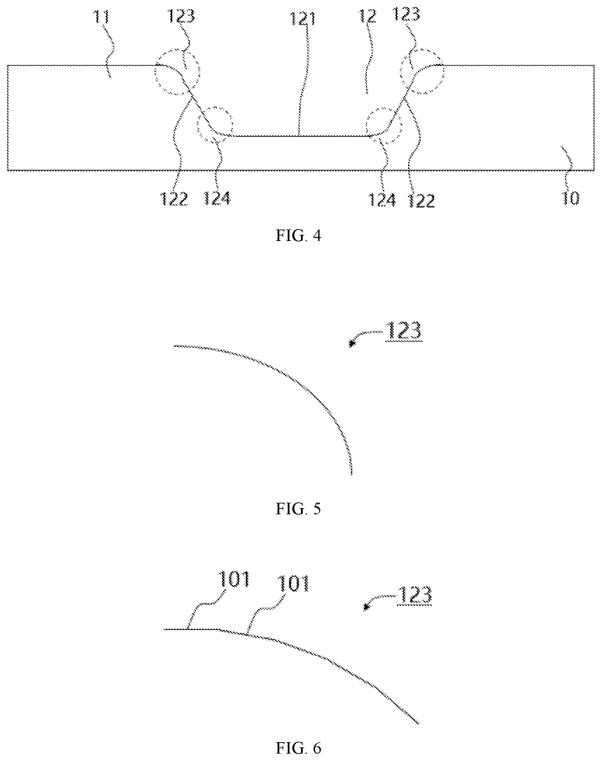

FIG. 4 is a second cross-sectional schematic diagram of a support layer according to an embodiment of the present application.

FIG. 5 is a schematic diagram of a chamfer with a circular arc shape according to an embodiment of the present application.

FIG. 6 is a schematic diagram of a chamfer formed by a plurality of line segments according to an embodiment of the present application.

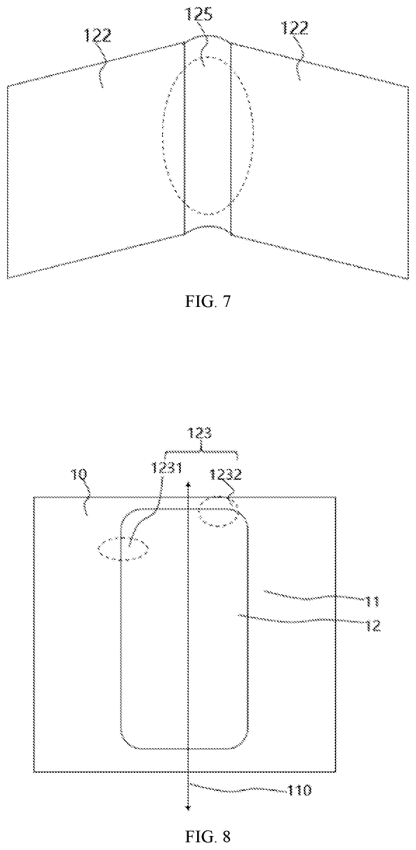

FIG. 7 is a partial side schematic diagram of a groove according to an embodiment of the present application.

FIG. 8 is a partial plan side schematic diagram of a groove according to an embodiment of the present application.

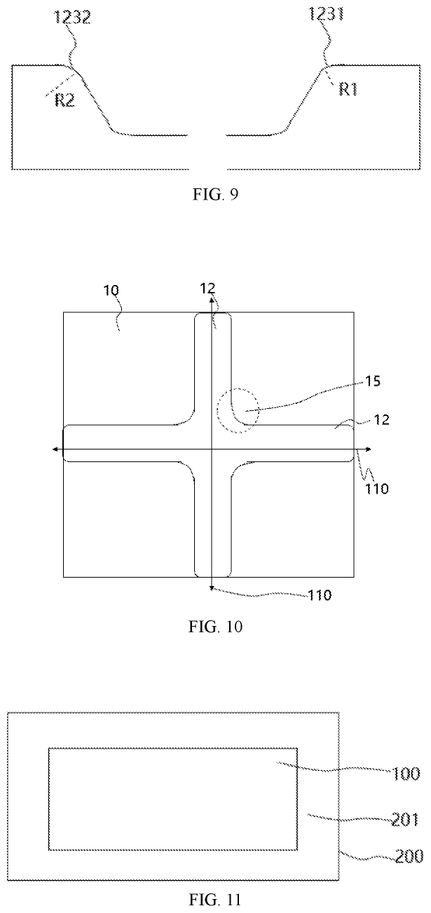

FIG. 9 is a schematic diagram of a first sub-chamfer and a second sub-chamfer according to an embodiment of the present application.

FIG. 10 is a plan top schematic diagram of a groove according to an embodiment of the present application.

FIG. 11 is a schematic diagram of a display terminal according to an embodiment of the present application.

### EMBODIMENTS OF INVENTION

### Details Description of the Embodiments

The following describes the technical solutions of the embodiments of the present application in a clear and complete manner with reference to the accompanying drawings in the embodiments of the present application. It will be apparent that the described embodiments are only a part of the embodiments of the present application, but not all of the embodiments. Based on the embodiments of the present application, all other embodiments obtained by those skilled in the art without creative effort fall within the scope of the present application. Furthermore, it should be understood that the specific embodiments described herein are intended only to illustrate and explain the present application and are not intended to limit the present application. Terms “up” and “low” are used in the present application in the absence of a reverse description, generally referring to the upper and lower parts of the device in actual use or operation, in particular in the drawing direction; the terms “in” and “out” are for the profile of the device.

An embodiment of the present application provides a display panel. The display panel includes a display panel body including at least a bending portion, and a support layer disposed on a back side of the display panel body. The support layer includes a pattern portion corresponding to the bending portion, wherein the pattern portion includes a flat portion and at least one groove, and a transition portion where the groove is connected to the flat portion is disposed with a chamfer.

Embodiments of the present application provide a display panel and a display terminal. Detailed description will be given below. It should be noted that the order of description of the following embodiments is not a limitation on the preferred order of the embodiments.

### Example 1

Referring to FIGS. 1, 2, 3 and 4, FIG. 1 is a cross-sectional schematic diagram of a display panel 100 according to an embodiment of the present application. FIG. 2 is a top schematic diagram of the display panel 100 according to an embodiment of the present application.

The display panel 100 is provided in an embodiment of the present application. The display panel 100 includes a display panel body 20 and a support layer 10. The display panel body 20 includes at least a bending portion FF1 and a non-bending portion CC1. The support layer 10 includes a pattern portion FF2 corresponding to the bending portion FF1 and a flat portion 11 corresponding to the non-bending portion CC1. The pattern portion FF2 includes at least one groove 12, and a transition portion where the groove 12 is connected to the flat portion 11 is disposed with a chamfer. More specifically, the transition portion where the groove 12 in connected to the flat portion 11 is disposed with a first chamfer 123 (as shown by a circle with dotted lines in the Figure).

Specifically, the display panel 100 includes a display panel body 20 and a support layer 10. The support layer 10 is disposed on a back side of the display panel body 20. The display panel body 20 may include a front side for displaying an image for viewing, and a back side of the front side is the back side. The support layer 10 is disposed on the back side of the display panel body 20 to provide a support for the display panel 20.

Specifically, the display panel body 20 includes at least one bending portion FF1, that is, the display panel body 20 may include a non-bending portion CC1 other than the bending portion FF1, or the display panel body 20 may include more than one bending portion FF1. When the display panel body 20 includes the bending portion FF1 in two directions, two bending directions may intersect, which is not limited here.

Specifically, in an embodiment of the present application, as shown in FIG. 2, it is preferable that the display panel body 20 includes at least two bending portions FF1, the support layer 10 correspondingly includes at least two pattern portions FF2, and the two bending portions FF1 may intersect, for example, the two bending portions FF1 are perpendicular to each other. The two pattern portions FF2 also intersect, for example, the two pattern portions FF2 are perpendicular to each other.

In some embodiments, the pattern portion FF2 is located on a surface of the support layer 10 away from the display panel body 20.

Specifically, a surface of the support layer 10 close to the display panel body 20 is a flat surface, and a surface of the support layer 10 away from the display panel body 20 is provided with a pattern portion FF2. The surface of the support layer 10 close to the display panel body 20 is the flat surface, and can provide good support for the display panel body 20. Meanwhile, the surface of the support layer 10 away from the display panel body 20 is provided with the pattern portion FF2, so that the support layer 10 can further be easily bent, a bending stress can be reduced, and a bending performance can be improved.

Specifically, in an embodiment of the present application, the support layer 10 is provided with a pattern portion corresponding to the bending portion FF1 of the display panel body 20, and the pattern portion includes at least one groove 12. The transition portion where the groove 12 is connected to the flat portion 11 is provided with the first chamfer 123. By providing the first chamfer 123, sharp corners or edges of the transition portion where the groove 12 is connected to the flat portion 11 can be removed. During a bending process, a stress concentration of the support layer 10 is prevented at the transition portion where the groove 12 is connected to the flat portion 11, thereby preventing an occurrence of cracks and improving a reliability of the support layer 10. Further, when the support layer 10 includes two or more pattern portions FF2, that is, when the display panel 100 can be bent in an intersected direction, the first chamfer 123 is provided at the transition portion where the groove 12 is connected to the flat portion 11 in a plurality of bending directions, so that the stress concentration does not occur, cracks are prevented, and the reliability of the support layer 10 is improved. It is understood that the bending direction refers to a direction perpendicular to a major axis direction of the bending portion FF1.

In some embodiments, as shown in FIG. 3, a bottom 121 of the groove 12 is a shape of an arc.

Specifically, the groove 12 includes a bottom 121 and a side wall 122, and the bottom 121 and the side wall 122 of the groove 12 are integrally connected to form an arc shape, for example, a circular arc shape. In this case, furthermore, the bottom 121 and the side wall 122 of the groove 12 transitions smoothly without a sharp angle or edge, so as to prevent an occurrence of stress concentration, thereby preventing an occurrence of cracks, and improving a reliability of the support layer 10.

In some embodiments, as shown in FIG. 4, the groove 12 includes a bottom 121, and a side wall 122 connected between the bottom 121 and the flat portion 11. A transition portion where the side wall 122 is connected to the bottom 121 of the groove 12 is disposed with a second chamfer 124 (as shown by a circle with dotted lines).

Specifically, the bottom 121 of the groove 12 may have a planar or curved surface or the like, and a transition portion where the bottom 121 is connected to the side wall 122 is disposed with a second chamfer 124, so that there is no sharp corner or edge in this portion, thereby preventing an occurrence of stress concentration, preventing an occurrence of cracks, and improving a reliability of the support layer 10.

Referring to FIG. 5 and FIG. 6, which are enlarged views of the first chamfer 123. FIG. 5 is a schematic diagram of a circular arc-shaped chamfer. FIG. 6 is a schematic diagram of a chamfer formed by a plurality of line segments.

In some embodiments, the first chamfer 123 is an arc-shaped chamfer or a chamfer formed by a plurality of line segments. Two adjacent line segments are connected in smoothly transition.

Specifically, the first chamfer 123 or/and the second chamfer 124 may be an arc-shaped chamfer or a chamfer formed by a plurality of line segments. When the first chamfer 123 or/and the second chamfer 124 are formed by the plurality of line segments, two adjacent line segments 101 are connected in smoothly transition, and an angle between any two of the plurality of line segments 101 adjacent to each other is greater than 90°, so that sharp angles and edges are eliminated.

In an embodiment of the present application, the transition portion where the groove 12 is connected to the flat portion 11 is disposed with the first chamfer 123. By disposing the first chamfer 123, sharp corners or edges of the transition portion where the groove 12 is connected to the flat portion 11 can be removed, thereby preventing the stress concentration in the transition portion where the groove 12 is connected to the flat portion 11, thereby preventing the occurrence of cracks and improving the reliability of the support layer 10. In addition, when the support layer 10 includes two or more pattern portions FF2, that is, when the display panel 100 is bent in an intersected direction, the transition portion where the groove 12 is connected to the flat portion 11 is disposed with the first chamfer 123 in a plurality of directions or in any direction, so that the stress concentration does not occur, cracks are prevented, and the reliability of the support layer is improved.

Further, the transition portion where the side wall 122 of the groove 12 is connected to the bottom 121 of the groove 121 is disposed with the second chamfer 124, which eliminates sharp corners or edges of the transition portion and prevents the stress concentration at the transition portion where the side wall 122 is connected to the bottom 121, and prevents crack.

In an embodiment of the present application, by disposing the transition portion where the groove 12 is connected to the flat portion 11 with the first chamfer 123 or/and the transition portion where the side wall 122 of the groove 12 is connected to the bottom 121 of the groove 12 with the second chamfer 124, it is possible to completely eliminate sharp corners or edges caused by the provision of the groove, so that each portion smoothly transitions, thereby relieving the stress concentration, which is particularly suitable for the display panel 100 with the bending portions in two intersected directions, and thereby improving the bending performance of the display panel 100.

In an embodiment of the present application, the first chamfer 123 is disposed at a plurality of transition portions where the groove 12 is connected to the flat portion 11, for example, the first chamfer 123 and/or the second chamfer 124 are disposed perpendicular to a first bending direction and a second bending direction, and the first bending direction and the second bending direction intersected with each other. When the display panel 100 is bent, a deformation occurs at a portion perpendicular to a bending direction, and the stress concentration easily occurs. By providing the embodiment of the present application, sharp corners or edges perpendicular to the bending direction caused by the groove are eliminated, so that each portion smoothly transitions, thereby relieving the stress concentration, which is particularly suitable for the display panel 100 with the bending portions of the two intersected directions.

It should be noted that a thickness of the flat portion 11 of the support layer 10 is greater than a thickness of the side wall 122, and the thickness of the side wall 122 is greater than a thickness of the bottom 121.

It should be noted that the chamfer shape and degree of the first chamfer 123 or/and the second chamfer 124 may be different within a same groove or among different grooves. For example, the first chamfer 123 is an arc-shaped chamfer, and the second chamfer 124 is a chamfer formed by a plurality of line segments. For example, shapes of two first chamfers 123 opposite to each other in a same groove 12 are circular arc, and radii of circular arc shapes of the first chamfers 123 are different. In this case, the stress concentration can be avoided, and the occurrence of cracks can be prevented.

Specifically, the display panel body 20 may be a body of an organic light-emitting display panel. For example, the display panel body 20 includes an array substrate, a light-emitting component provided on the array substrate, and an encapsulation layer provided on the light-emitting component. The structure of the display panel body 20 is not limited here.

### Example 2

This embodiment is same as or similar to the above embodiment except that a transition portion where adjacent side walls 122 of the groove 12 are connected to is disposed with a third chamfer 125.

Referring to FIG. 7, FIG. 7 illustrates a partial side schematic diagram of the groove 12.

Specifically, the groove 12 includes a plurality of side walls 122. The transition portion where adjacent side walls 122 are connected to is disposed with the third chamfer 125. The third chamfer 125 may be an arc-shaped chamfer or a chamfer formed by a plurality of line segments, so that the sharp corners or edges at adjacent side walls 122 are eliminated, thereby avoiding the cracks and improving the reliability of the display panel. In particular, in the display panel 100 with a plurality of bending directions, for example, in the display panel 100 which can be arbitrarily bent, when the display panel is bent, a bending shaft corresponds to the transition portion where the adjacent side walls 122 are connected to. In this case, a stress at the transition portion where the adjacent side walls 122 are connected to is very large, and the transition portion where the adjacent side walls 122 are connected to is disposed with the third chamfer 125, so that the stress can be prevented from being concentrated on a point and the occurrence of cracks can be avoided.

It should be noted that, in various embodiments of the present application, the first chamfer 123, the second chamfer 124, and the third chamfer 125 may be a circular arc-shaped chamfer or a chamfer formed by a plurality of line segments, and sharp corners or edges between adjacent side walls 122 may be eliminated, so that the stress concentration is prevented from occurring at transition portions where adjacent side walls 122 are connected, and cracks are avoided. Therefore, the radii of the first chamfer 123, the second chamfer 124, and the third chamfer 125 are greater than 90° and less than 180°. At the same time, the closer the radii of the first chamfer 123, the second chamfer 124, and the third chamfer 125 to 180°, the more helpful is on the reduction of stress concentration and the avoidance of cracks.

### Example 3

The present embodiment is same as or similar to the above embodiment except that the bending portion FF1 includes a bending shaft 110, the first chamfer 123 includes a first sub-chamfer 1231 and a second sub-chamfer 1232, the second sub-chamfer 1232 is located on the bending shaft 110, and the radius R2 of the second sub-chamfer 1232 is different from the radius R1 of the first sub-chamfer 1231.

Referring to FIGS. 8 and 9, FIG. 8 is a partial plan side schematic diagram of the groove 12, and FIG. 9 is a schematic diagram of a first sub-chamfer 1231 and a second sub-chamfer 1232.

Specifically, the bending shaft 110 refers to a direction of a major axis of the bending portion, and the display panel 100 is bent around the bending shaft 110. The second sub-chamfer 1232 is located on the bending shaft 110, this means an included angle between an edge or a portion provided with the second sub-chamfer 1232 and the bending shaft is 90° or approximately 90°. When the display panel 100 or the support layer 10 is bent, edges or portions with the second sub-chamfer 1232 are prone to deformation and stress concentration. The first sub-chamfer 1231 is not located on the bending shaft, this is, an included angle between an edge or a portion provided with the first sub-chamfer 1231 and the bending shaft is 0° or approximately 0°. When the display panel 100 or the support layer 10 is bent, edges or portions with the first sub-chamfer 1231 are not prone to deformation and stress concentration. FIG. 8 illustrates a second sub-chamfer 1232 located on the bending shaft 110, an included angle between the edge or portion with the second sub-chamfer 1232 and the bending shaft 110 is 90°. FIG. 8 illustrates the first sub-chamfer 1231 not located on the bending shaft 110, and an included angle between the edge or portion with the first sub-chamfer 1231 and the bending shaft 110 is 0°.

Specifically, by setting the radius R2 of the second sub-chamfer 1232 to be different from the radius R1 of the first sub-chamfer 1231, it is possible to adapt a size of the second sub-chamfer 1232 and a size of the first sub-chamfer 1231 to the bending shaft, thereby increasing an application range of the second sub-chamfer 1232 and the first sub-chamfer 1231.

Further, the radius R2 of the second sub-chamfer 1232 is greater than the radius R1 of the first sub-chamfer 1231.

Specifically, since the included angle between the edge or the portion with the second sub-chamfer 1232 and the bending shaft is 90° or approximately 90°, therefore when the display panel 100 or the support layer 10 is bent, the edge or the portion with the first sub-chamfer 1231 are main portions where deformation occurs, the stress concentration is easily generated. The radius R2 of the second sub-chamfer 1232 is greater than the radius R1 of the first sub-chamfer 1231, that is, the chamfering degree of the second sub-chamfer 1232 is increased, so that the transition between the side wall 122 of the groove 12 and the flat portion 11 is more gentle, can better eliminate the deformation and stress concentration caused by a thickness change, and therefore, can better eliminate the stress concentration, thereby prevent the occurrence of cracks and improve the bending performance.

### Example 4

This embodiment is same as or similar to the above embodiment except that a case where the support layer 10 includes a plurality of grooves 12 is further described in detail.

Referring to FIG. 10, FIG. 10 is a plan top schematic diagram of the support layer 10 with a plurality of grooves 12.

In some embodiments, the support layer 10 includes two intersected grooves 12, and the edges of the intersected transition portions of the two grooves 12 are arc-shaped or a plurality of line segments in a smooth transition connection.

Specifically, the display panel 100 includes two bending portions FF1, and each bending portion FF1 includes a bend shaft 110. Two grooves 12 are intersected, then two bending portions FF1 are intersected, and two bending shafts 110 are intersected.

Specifically, in a preferred embodiment, the two grooves 12 are perpendicular to each other, the two bending portions FF1 are perpendicular to each other, and the two bending shafts 110 are perpendicular to each other. At this time, the two intersected grooves 12 have a cross shape, and the two bending shafts 110 have a cross shape.

Specifically, the edges of the intersected portions of the two grooves 12 are arc-shaped or a plurality of line segments in smoothly transition connection, i.e., the intersected portion 15 in FIG. 10 (as shown by a circle with dotted lines in the figure) is arc-shaped or a plurality of line segments in smoothly transition connection, or an orthogonal projection of the intersected portion 15 on the back side surface of the support layer 10 is arc-shaped or a plurality of line segments in smoothly transition connection.

Specifically, in the display panel 100 with a plurality of bending directions, for example, in the display panel 100 with two intersected bending directions (the bending axis 110 with two intersected bending directions), for example, in the display panel 100 that can be arbitrarily bent, the intersected portions 15 are deformed and stress-concentrated when the display panel 100 is bent in a plurality of directions, and this portion is prone to stress concentration. The intersected portions 15 are arc-shaped or a plurality of line segments in a smooth transition connection, and the deformation and stress when the display panel 100 is bent in a plurality of bending directions can be eliminated or reduced, thereby preventing the occurrence of cracks and improving the bending performance.

### Example 5

Referring to FIG. 11, FIG. 11 is a schematic diagram of a display terminal 200 according to an embodiment of the present application.

An embodiment of the present application provides a display terminal 200 including a terminal 201 and a display panel 100 as described in any one of the above embodiments, and the terminal 201 is integrated with the display panel 100.

It should be noted that the chamfer in the above-described embodiment refers to a chamfer formed by rounded corners or/and chamfered edges, such as an arc-shaped chamfer or a chamfer formed by a plurality of line segments.

It should be noted that the transition portion in the above embodiment refers to a connection portion, that is, a connection portion of two adjacent portions.

The display panel and display terminal provided in the embodiments of the present application are described in detail above. The principles and embodiments of the present application are described by using specific examples herein. The description of the embodiments is merely intended to help understand the method and core ideas of the present application. At the same time, a person skilled in the art may make changes in the specific embodiments and application scope according to the idea of the present application. In conclusion, the content of the specification should not be construed as a limitation to the present application.

1. A display panel, wherein the display panel comprises:
a display panel body comprising at least a bending portion and a non-bending portion;
a support layer disposed on a back side of the display panel body, the support layer comprising a pattern portion corresponding to the bending portion, and a flat portion corresponding to the non-bending portion;
wherein the pattern portion comprises at least one groove, and a transition portion where the groove is connected to the flat portion is disposed with a chamfer.

2. The display panel of claim 1, wherein the transition portion where the groove is connected to the flat portion is disposed with a first chamfer, and a shape of the first chamfer is a chamfer with a circular arc shape or a chamfer having a plurality of line segments.

3. The display panel of claim 2, wherein the first chamfer has a shape of the chamfer having the plurality of the line segments, and two line segments adjacent to each other are connected in smooth transition.

4. The display panel of claim 1, wherein a bottom of the groove is arc-shaped.

5. The display panel of claim 1, wherein the groove comprises a bottom, and a side wall connected between the bottom and the flat portion, a transition portion where the side wall is connected to the bottom of the groove is disposed with a second chamfer.

6. The display panel of claim 2, wherein the groove comprises a plurality of side walls, and a transition portion where the side walls adjacent to each other are connected is disposed with a third chamfer.

7. The display panel of claim 2, wherein the bending portion comprises a bending shaft, the first chamfer comprises a first sub-chamfer and a second sub-chamfer, the second sub-chamfer is located on the bending shaft, and a radius of the second sub-chamfer is different from a radius of the first sub-chamfer.

8. The display panel of claim 7, wherein the radius of the second sub-chamfer is greater than the radius of the first sub-chamfer.

9. The display panel of claim 1, wherein the support layer comprises two grooves intersected with each other, and an edge of a transition portion where the two grooves intersect is arc-shaped or a shape of a plurality of line segments connected in smooth transition.

10. The display panel of claim 1, wherein the pattern portion is located on a surface of the support layer away from the display panel body.

11. A display terminal, wherein the display terminal comprises a terminal and a display panel, the terminal is integrated with the display panel, and the display panel comprises:
a display panel body comprising at least a bending portion and a non-bending portion;
a support layer disposed on a back side of the display panel body, the support layer comprising a pattern portion corresponding to the bending portion and a flat portion corresponding to the non-bending portion;
wherein the pattern portion comprises at least one groove, and a transition portion where the groove is connected to the flat portion is disposed with a chamfer.

12. The display terminal of claim 11, wherein the transition portion where the groove is connected to the flat portion is disposed with a first chamfer, and a shape of the first chamfer is a chamfer with a circular arc shape or a chamfer having a plurality of line segments.

13. The display terminal of claim 12, wherein the first chamfer has a shape of the chamfer having the plurality of the line segments, and two line segments adjacent to each other are connected in smooth transition.

14. The display terminal of claim 11, wherein a bottom of the groove is arc-shaped.

15. The display terminal of claim 11, wherein the groove comprises a bottom, and a side wall connected between the bottom and the flat portion, a transition portion where the side wall is connected to the bottom of the groove is disposed with a second chamfer.

16. The display terminal of claim 12, wherein the groove comprises a plurality of side walls, and a transition portion where the side walls adjacent to each other are connected is disposed with a third chamfer.

17. The display terminal of claim 12, wherein the bending portion comprises a bending shaft, the first chamfer comprises a first sub-chamfer and a second sub-chamfer, the second sub-chamfer is located on the bending shaft, and a radius of the second sub-chamfer is different from a radius of the first sub-chamfer.

18. The display terminal of claim 17, wherein the radius of the second sub-chamfer is greater than the radius of the first sub-chamfer.

19. The display terminal of claim 11, wherein the support layer comprises two grooves intersected with each other, and an edge of a transition portion where the two grooves intersect is arc-shaped or a shape of a plurality of line segments connected in smooth transition.

20. The display terminal of claim 11, wherein the pattern portion is located on a surface of the support layer away from the display panel body.
